(19) United States
(12) Patent Application Publication
(10) Pub. No.: US 2007/0221970 A1
(43) Pub. Date: Sep. 27, 2007

(54) Manufacturing method of semiconductor device and semiconductor device

(75) Inventors: Masaru Kadoshima, Tokyo (JP); Toshihide Nabatame, Tokyo (JP)

Correspondence Address: Stanley P. Fisher;Reed Smith LLP, Suite 1400, 3110 Fairview Park Drive, Falls Church, VA, 22042-4503, US

(73) Assignee: Renesas Technology Corp.

(21) Appl. No.: 11/715,353

(22) Filed: Mar. 8, 2007

(30) Foreign Application Priority Data
Mar. 17, 2006 (JP) JP2006-075150

(51) Int. Cl. H01L 29/76; H01L 21/8234

(52) U.S. Cl. 257/288; 438/197

(57) ABSTRACT

In a manufacturing process of a semiconductor device having a CMISFET, first, a silicon film and a first metal film made of a first metal are reacted with each other through heat treatment, thereby forming a gate electrode of a p-channel type MISFET and a dummy gate electrode of an n-channel type MISFET, which are formed of metal silicide. Subsequently, an insulating film is formed so as to cover the gate electrode but expose the dummy electrode, and then, a metal film formed of a second metal having a work function lower than that of the first metal. The metal film contacts with the dummy gate but not with the gate electrode due to the insulating film interposing therebetween. Thereafter, through heat treatment, the dummy gate electrode and the metal film are reacted with each other to form a gate electrode of the n-channel type MISFET.

### CROSS-REFERENCE TO RELATED APPLICATION

The present application claims priority from Japanese Patent Application No. JP 2006-75150 filed on Mar. 17, 2006, the content of which is hereby incorporated by reference into this application.

### TECHNICAL FIELD OF THE INVENTION

The present invention relates to a manufacturing method of a semiconductor device and a semiconductor device. More particularly, the present invention relates to a technique effectively applied to a manufacturing technology of a semiconductor device, which comprises a MISFET with a metal gate electrode, and a semiconductor device.

### BACKGROUND OF THE INVENTION

A MISFET (Metal Insulator Semiconductor Field Effect Transistor: MIS Field Effect Transistor, MIS Transistor) can be made by: forming a gate insulator on a semiconductor substrate; forming a gate electrode on the gate insulator; and forming a source/drain region by ion implantation or the like.

Further, in a CMISFET (Complementary Metal Insulator Semiconductor Field Effect Transistor), in order to realize low threshold voltage in both an n-channel type MISFET and a p-channel type MISFET, gate electrodes are formed using different materials having different work functions (Fermi level in the case of polysilicon), that is, the so-called dual-gate structure has been employed. More specifically, by introducing an n-type impurity and a p-type impurity into a polysilicon film which forms gate electrodes of the n-channel type MISFET and p-channel type MISFET, respectively, the work function (Fermi level) of the gate-electrode material of the n-channel type MISFET is set to a value near the conduction band of silicon, and the work function (Fermi level) of the gate-electrode material of the p-channel type MISFET is set to a value near the valence band of silicon, thereby lowering their threshold voltages.

However, in recent years, along with scaling of CMISFET elements, the thickness of a gate insulator has been more and more reduced, and therefore, in the case of using a polysilicon film as a gate electrode, the influences of gate electrode depletion have become unignorable. Thus, there is a technology for suppressing gate electrode depletion by replacing gate electrodes with metal gate electrodes.

U.S. Pat. No. 6,599,831 (Patent Document 1) discloses a technology, in which a polysilicon film doped with a dopant is reacted with a nickel film formed thereon, thereby forming a gate electrode made of nickel silicide.

In addition, Japanese Patent Application Laid-Open Publication No. 2004-165346 (Patent Document 2) discloses a technology for a semiconductor device with a dual-gate structure comprising: a semiconductor substrate; a first transistor formed on the semiconductor substrate and having a first gate electrode and a first conductive-type channel diffusion region; and a second transistor formed on the semiconductor substrate and having a second gate electrode and a second conductive-type channel region, in which at least one of the first and second gate electrodes is made of a substitution metal material containing a work-function adjusting metal, and the substitution metal material containing a work-function adjusting metal has a work function capable of operating a corresponding transistor with a threshold voltage almost symmetrical to that of another transistor.

### SUMMARY OF THE INVENTION

According to the study by the inventors of the present invention, the following problems have been found.

In the case of using a polysilicon film as a gate electrode of a MISFET, influences of depletion in the gate electrode made of polysilicon may occur. On the contrary, by forming a gate electrode from a metal material such as nickel silicide, it is possible to suppress depletion phenomenon in the gate electrode and eliminate parasitic capacitance. Accordingly, it becomes possible to achieve the miniaturization of MISFET elements (thickness scaling of gate insulator).

However, even in the case of using a metal film such as nickel silicide for a gate electrode material, it is desired to improve performance of semiconductor devices by lowering threshold voltages of both the n-channel type MISFET and p-channel type MISFET of a CMISFET. For its achievement, it is required to control work functions of gate electrodes of the n-channel type MISFET and p-channel type MISFET.

When using metal-rich metal silicides as the gate electrode of a p-channel type MISFET, it is possible to form the gate electrode having a high effective work function suitable for the gate electrode of a p-channel type MISEFT. On the other hand, materials with a low effective work function suitable for the gate electrode of an n-channel type MISFET have poor heat stability and are difficult to handle.

It is conceivable that, after forming a gate stack using a polysilicon film, by a technique for replacing this polysilicon film with Al (metal mainly made of Al), an Al-replaced gate electrode is formed as the gate electrode of an n-channel type MISFET. However, if an Al-replaced gate electrode and a metal-silicide-based gate electrode are formed for the n-channel type MISFET and p-channel type MISFET, respectively, the number of manufacturing processes is increased. For example, it is required that, after selectively covering an n-channel type MISFET formation region with a cap insulating film, a nickel-silicide-based gate electrode for a p-channel type MISFET is formed, and then, after selectively covering a p-channel type MISFET formation region with another cap insulating film, an Al-replacement process is performed in the n-channel type MISFET formation region. Therefore, there is a possibility that the number of manufacturing processes of a semiconductor device is increased, and accordingly, the cost of manufacturing a semiconductor device is increased and the manufacturing yield thereof is lowered.

An object of the present invention is to provide a technique capable of improving performance of semiconductor devices.

Another object of the present invention is to provide a technique capable of decreasing the number of manufacturing processes of semiconductor devices.

The above and other objects and novel characteristics of the present invention will be apparent from the description of this specification and the accompanying drawings.

The typical ones of the inventions disclosed in this application will be briefly described as follows.

In the present invention, after a first gate electrode of a p-channel type first MISFET made of a metal silicide containing a first metal as its constituent element and a dummy gate electrode of an n-channel type second MISFET are formed, a metal film made of a second metal having a work function lower than that of the first metal is formed so as to contact with the dummy gate electrode but not with the first gate electrode, and thereafter, the dummy gate electrode and the metal film are reacted through heat treatment to form a second gate electrode of the second MISFET.

Further, in the present invention, by reacting a silicon film with a first metal film made of a first metal through heat treatment, a first gate electrode of a p-channel type first MISFET made of a metal silicide containing the first metal as its constituent element and a dummy gate electrode of an n-channel type second MISFET are formed. Subsequently, a second metal film made of a second metal having a work function lower than that of the first metal is formed so as to contact with the dummy gate but not with the first gate electrode. Thereafter, a second gate electrode of the second MISFET is formed by reacting the dummy gate electrode with the second metal film through heat treatment.

Moreover, in the present invention, a gate electrode of a p-channel type MISFET is formed of a metal silicide film containing a first metal as its constituent element, and a gate electrode of an n-channel type MISFET is formed of a conductive film containing Si, the first metal, and a second metal having a work function lower than that of the first metal as its constituent elements.

The effects obtained by typical aspects of the present invention will be briefly described below.

Performance of a semiconductor device can be improved.

Further, the number of steps in the manufacturing process of a semiconductor device can be reduced.

### BRIEF DESCRIPTIONS OF THE DRAWINGS

FIG. 1 is a cross-sectional view showing main parts of a semiconductor device in a manufacturing process according to one embodiment of the present invention;

FIG. 2 is a cross-sectional view showing main parts of the semiconductor device in a manufacturing process continued from FIG. 1;

FIG. 3 is a cross-sectional view showing main parts of the semiconductor device in a manufacturing process continued from FIG. 2;

FIG. 4 is a cross-sectional view showing main parts of the semiconductor device in a manufacturing process continued from FIG. 3;

FIG. 5 is a cross-sectional view showing main parts of the semiconductor device in a manufacturing process continued from FIG. 4;

FIG. 6 is a cross-sectional view showing main parts of the semiconductor device in a manufacturing process continued from FIG. 5;

FIG. 7 is a cross-sectional view showing main parts of the semiconductor device in a manufacturing process continued from FIG. 6;

FIG. 8 is a cross-sectional view showing main parts of the semiconductor device in a manufacturing process continued from FIG. 7;

FIG. 9 is a cross-sectional view showing main parts of the semiconductor device in a manufacturing process continued from FIG. 8;

FIG. 10 is a cross-sectional view showing main parts of the semiconductor device in a manufacturing process continued from FIG. 9;

FIG. 11 is a cross-sectional view showing main parts of the semiconductor device in a manufacturing process continued from FIG. 10;

FIG. 12 is a cross-sectional view showing main parts of the semiconductor device in a manufacturing process continued from FIG. 11;

FIG. 13 is a cross-sectional view showing main parts of the semiconductor device in a manufacturing process continued from FIG. 12;

FIG. 14 is a graph showing C-V characteristics of MOS capacitors;

FIG. 15 is a cross-sectional view showing main parts of a semiconductor device in a manufacturing process according to another embodiment of the present invention;

FIG. 16 is a cross-sectional view showing main parts of the semiconductor device in a manufacturing process continued from FIG. 15;

FIG. 17 is a cross-sectional view showing main parts of the semiconductor device in a manufacturing process continued from FIG. 16; and

FIG. 18 is a cross-sectional view showing main parts of the semiconductor device in a manufacturing process continued from FIG. 17.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be basically omitted except when needed.

In addition, in the accompanying drawings referred in the descriptions of the embodiment, hatching may be omitted even in cross-sectional views to make them easy to see. To the contrary, hatching may be added even in plan views to make them easy to see.

### First Embodiment

A semiconductor device and a manufacturing process thereof of the present embodiment will be described with reference to accompanying drawings. FIG. 1 to FIG. 13 are cross-sectional views of main parts of a semiconductor device, for example, a CMISFET (Complementary Metal Insulator Semiconductor Field Effect Transistor) in the manufacturing process thereof in one embodiment of the present invention.

As shown in FIG. 1, a semiconductor substrate (semiconductor wafer) 1 made of p-type single crystal silicon having resistivity of, for example, in a range of about 1 to 10 Ωcm is prepared. The semiconductor substrate 1 on which the semiconductor device on the present embodiment is formed has an n-channel type MISFET (Metal Insulator Semiconductor Field Effect Transistor) formation region 1A where an n-channel type MISFET is formed and a p-channel type MISFET formation region 1B where a p-channel type MISFET is formed. Then, device isolation regions 2 are formed in the main surface of the semiconductor substrate 1. The device isolation regions 2 are made of an insulating material such as silicon oxide and formed through, for example, STI (Shallow Trench Isolation) or LOCOS (Local Oxidization of Silicon).

Next, a p-type well 3 is formed in the region for forming an n-channel type MISFET (n-channel type MISFET formation region 1A) and an n-type well 4 is formed in the region for forming a p-channel type MISFET (p-channel type MISFET formation region 1B). The p-type well 3 is formed by the ion implantation of a p-type impurity such as boron (B) and the n-type well 4 is formed by the ion implantation of an n-type impurity such as phosphorus (P) or arsenic (As).

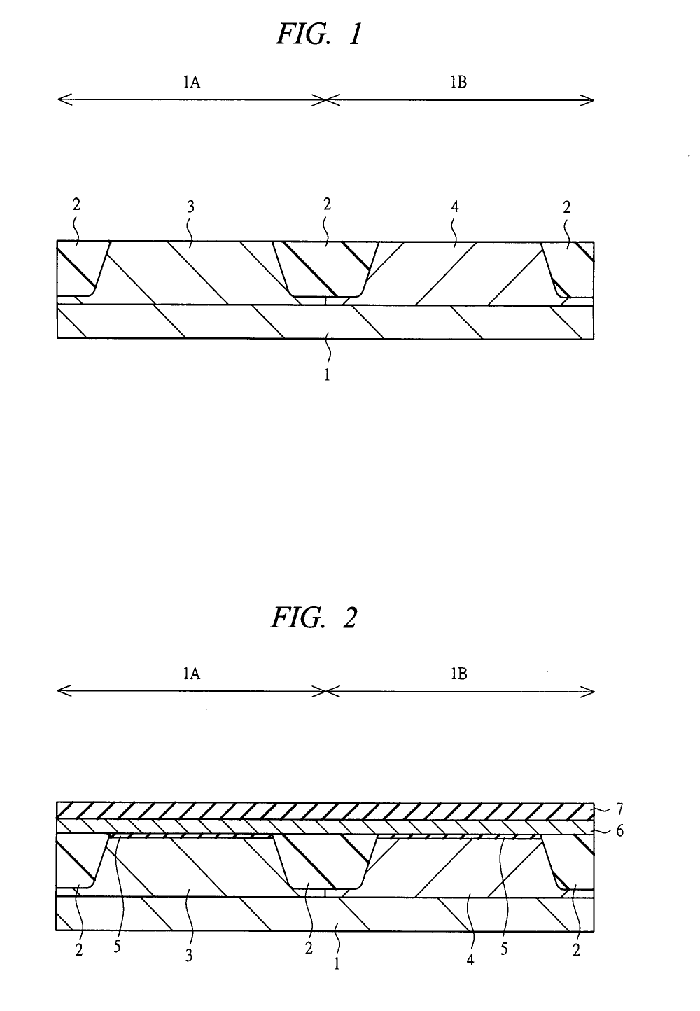

Next, as shown in FIG. 2, a gate insulator (an insulating film for a gate insulator) 5 is formed on the surfaces of the p-type well 3 and the n-type well 4. The gate insulator 5 is formed of, for example, a thin silicon oxide film and it can be formed through, for example, thermal oxidation. In the case where the gate insulator 5 is a silicon oxide film, it can be formed to have a thickness of, for example, in a range of about 2 to 4 nm. Further, a silicon oxynitride film can be used for the gate insulator 5. Still further, so-called high-k films (high dielectric constant films) such as hafnium oxide (HfO₂), hafnium aluminate (HfAlOₓ), hafnium silicate (HfSiOₓ), zirconia (zirconium oxide, ZrO₂), zirconium aluminate (ZrAlOₓ), zirconium silicate (ZrSiOₓ), lanthanum oxide (La₂O₃), and lanthanum silicate (LaSiOₓ) can be used for the gate insulator 5.

Next, a silicon film 6 is formed on the main surface of the semiconductor substrate 1, i.e., on the gate insulator 5. The silicon film 6 is, for example, a polycrystalline silicon film, and it can be formed through CVD (Chemical Vapor Deposition). When CVD is used for a method of deposition of the silicon film 6, the silicon film 6 can be formed without damaging the gate insulator 5 and others. The thickness of the silicon film 6 can be set to, for example, in a range of about 20 to 50 nm. Further, an amorphous silicon (non-crystalline silicon) film can be used as the silicon film 6. Further, it is more preferable that the silicon film 6 is a non-doped (undoped) silicon film to which no impurity is introduced (non-doped silicon film or non-doped amorphous silicon film). Note that, in the present embodiment, “non-doped” means that no impurity is introduced (added) intentionally, and the case where a small amount of impurity is unintentionally contained is included in “non-doped.”

Next, an insulating film (hard mask layer) 7 which is made of, for example, silicon oxide is formed on the silicon film 6. The thickness of the insulating film 7 can be set to, for example, in a range of about 50 to 100 nm.

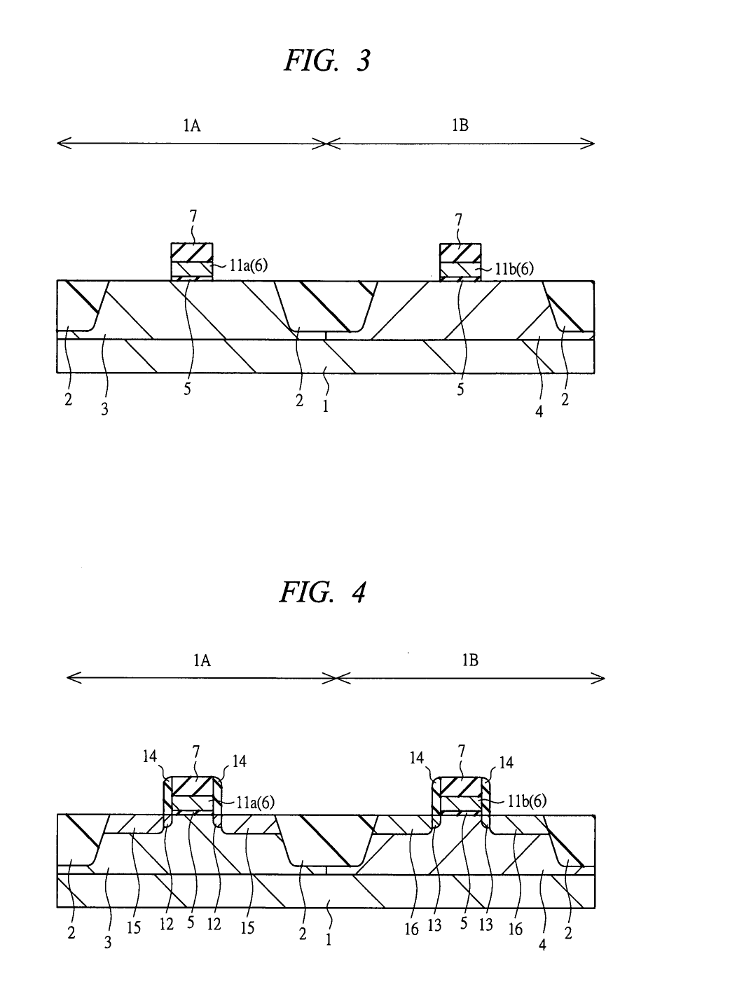

Next, as shown in FIG. 3, a layered film of the silicon film 6 and the insulating film 7 is patterned (i.e., processed or selectively removed) through photolithography and dry etching processes, or the like. The patterning can be made through, for example, RIE (Reactive Ion Etching). With the patterned silicon film 6, dummy electrodes (gate electrodes or dummy gate electrodes) 11a and 11b which are pseudo gate electrodes (dummy gate electrodes) are formed. More specifically, the dummy electrode 11a (second dummy electrode) which is the pseudo gate electrode for the n-channel type MISFET is formed by the silicon film 6 on the gate insulator 5 on the surface of the p-type well 3, and the dummy electrode 11b (first dummy electrode) which is the pseudo gate electrode for the p-channel type MISFET is formed by the silicon film 6 on the gate insulator 5 on the surface of the n-type well 4. Therefore, the dummy electrode 11a (second dummy electrode) is formed in a region where the gate electrode of the n-channel type MISFET formation region 1A is to be formed, and the dummy electrode 11b (first dummy electrode) is formed in a region where the gate electrode of the p-channel type MISFET formation region 1B is to be formed.

In this manner, the dummy electrode 11a for the n-channel type MISFET which is made of silicon (silicon film 6) is formed on the gate insulator 5 in the n-channel type MISFET formation region 1A, and the dummy electrode 11b for the p-channel type MISFET which is made of silicon (silicon film 6) is formed on the gate insulator 5 in the p-channel type MISFET formation region 1B.

Of the dummy electrodes 11a and 11b, the dummy electrode 11b formed in the p-channel type MISFET formation region 1B becomes a metal gate electrode of the p-channel type MISFET (gate electrode 31b described below) through a silicidation process described below (reaction process with a metal film 25 described below). Further, of the dummy electrodes 11a and 11b, the dummy electrode 11a formed in the n-channel type MISFET formation region 1A becomes a metal gate electrode of the n-channel type MISFET (gate electrode 31a described below) through a silicidation process (reaction process with the metal film 25) and a reaction process with another metal film (metal film 35 described below). It will be described in more details below.

Next, as shown in FIG. 4, (a pair of) n⁻-type semiconductor regions 12 are formed so as to be aligned with the dummy electrode 11a of the p-type well 3 through ion implantation of an n-type impurity such as phosphorus (P) or arsenic (As) into the regions on both sides of the dummy electrode 11a of the p-type well 3. Also, (a pair of) p⁻-type semiconductor regions 13 are formed so as to be aligned with the dummy electrode 11b of the n-type well 4 through ion implantation of a p-type impurity such as boron (B) into the regions on both sides of the dummy electrode 11b of the n-type well 4. In these ion implantation processes, since the insulating film 7 is provided on the dummy electrodes 11a and 11b and the insulating film 7 functions as a mask, no impurity ion is introduced into the dummy electrodes 11a and 11b. Furthermore, the order of the ion implantation process to form the n-type semiconductor regions 12 and the ion implantation process to form the p⁻-type semiconductor regions 13 described above is not meant to be restrictive.

Next, sidewalls (sidewall spacers or sidewall insulating films) 14 made of an insulating material such as silicon nitride are formed on the sidewalls of the dummy electrodes 11a and 11b. The sidewalls 14 can be formed by depositing a silicon nitride film on the semiconductor substrate 1 and subsequently performing anisotropic etching to the silicon nitride film.

After the sidewalls 14 are formed, through an ion implantation of an n-type impurity such as phosphorus (P) or arsenic (As) into the regions on both sides of the dummy electrode 11a and the sidewalls 14 of the p-type well 3, (a pair of) n⁺-type semiconductor regions 15 (source and drain) are formed so as to be aligned with the sidewalls 14 of the dummy electrode 11a on the p-type well 3. Further, through an ion implantation of a p-type impurity such as boron (B) into the regions on both sides of the dummy electrode 11b and the sidewalls 14 of the n-type well 4, (a pair of) p⁺-type semiconductor regions 16 (source and drain) are formed so as to be aligned with the sidewalls 14 of the dummy electrode 11b on the n-type well 4. In these ion implantation processes, since the insulating film 7 is provided on the dummy electrodes 11a and 11b and the insulating film 7 functions as a mask, no impurity ion is introduced into the dummy electrodes 11a and 11b. In addition, the order of the ion implantation process to form the n⁺-type semiconductor regions 15 and the ion implantation process to form the p⁺-type semiconductor regions 16 described above is not meant to be restrictive.

After the ion implantation processes, an annealing process (activation annealing or heat treatment) to activate the introduced impurities is performed. By performing the annealing in, for example, about 950° C., the impurities introduced to the n⁻-type semiconductor regions 12, the p⁻-type semiconductor regions 13, n⁺-type semiconductor regions 15 and the p⁺-type semiconductor regions 16 can be activated. In the case where the silicon film 6 is an amorphous silicon film when it is deposited, the silicon film 6 formed of an amorphous silicon film can be a polycrystalline silicon film through a process such as the annealing process.

Further, in the case where the silicon film 6 which comprises the dummy electrodes 11a and 11b is a silicon film into which an impurity is introduced, in particular, in the case where the silicon film 6 which comprises the dummy electrode 11b is a silicon film into which B (boron) is introduced (for example, B-doped polysilicon film), B (boron) penetrates the gate insulator 5 and diffuses into the channel region under the gate insulator 5 by the annealing process. However, in this embodiment, as described above, a non-doped silicon film to which no impurity is introduced is used for the silicon film which comprises the dummy electrodes 11a and 11b. Therefore, it is possible to prevent impurities such as B (boron) from penetrating the gate insulator 5 and diffusing into the channel region under the gate insulator 5 by this annealing process.

Through the above-described annealing process (activation annealing), impurities introduced into the n⁻-type semiconductor regions 12, the p⁻-type semiconductor regions 13, the n⁺-type semiconductor regions 15 and the p⁺-type semiconductor regions 16 are activated. In this manner, n-type semiconductor regions (impurity diffused layers) which function as the source or drain of the n-channel type MISFET are formed from the n⁺-type semiconductor regions 15 and n⁻-type semiconductor regions 12, and p-type semiconductor regions (impurity diffused layers) which function as the source or drain of the p-channel type MISFET are formed from the p⁺-type semiconductor regions 16 and the p⁻-type semiconductor regions 13. The n⁺-type semiconductor regions 15 have an impurity concentration higher than that of the n⁻-type semiconductor regions 12, and the p⁺-type semiconductor regions 16 have an impurity concentration higher than that of the p⁻-type semiconductor regions 13.

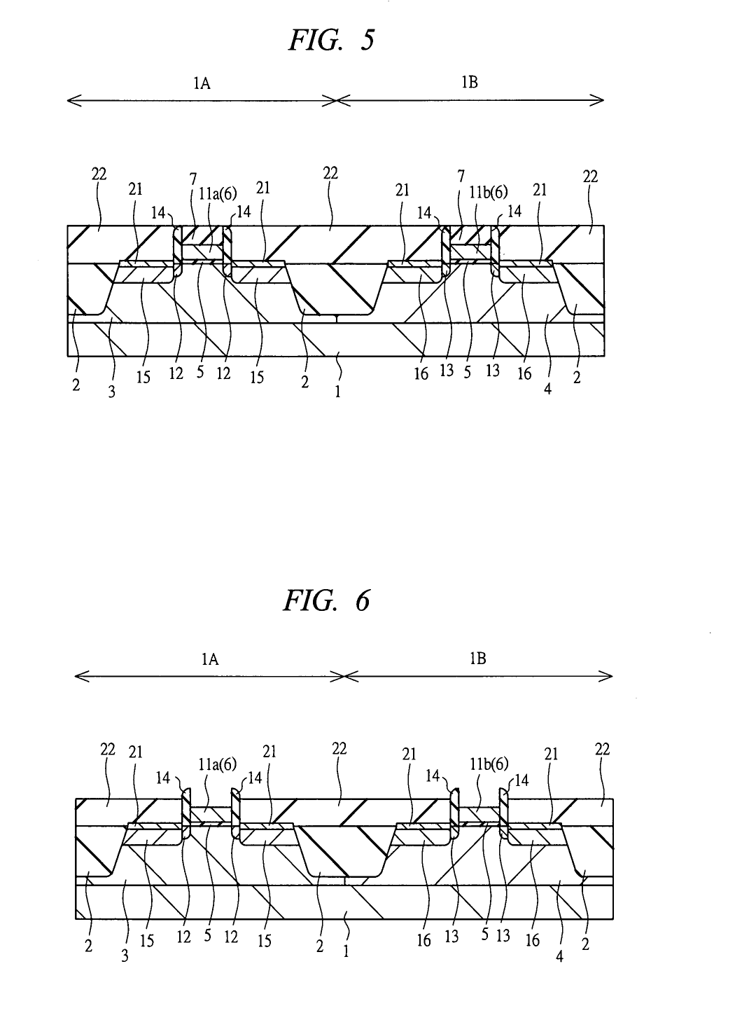

Next, an etching process (for example, wet etching using diluted hydrofluoric acid) is performed as necessary to expose the surfaces of the n⁺-type semiconductor regions 15 and the p⁺-type semiconductor regions 16 (at this time, the insulating films 7 on the dummy electrodes 11a and 11b are left and the surfaces of the dummy electrodes 11a and 11b are not exposed). After that, as shown in FIG. 5, a metal film such as a cobalt (Co) film is deposited on the semiconductor substrate 1 including on the n⁺-type semiconductor regions 15 and the p⁺-type semiconductor regions 16, and a heat treatment is performed thereto to form a metal silicide layer (metal silicide film) 21 made of, for example, cobalt silicide on each surface of the n⁺-type semiconductor regions 15 and the p⁺-type semiconductor regions 16. Consequently, diffusion resistance and contact resistance of the source and drain can be lowered. Thereafter, unreacted part of the metal film (cobalt film) is removed. At this time, since the insulating films 7 exist on the dummy electrodes 11a and 11b, no metal silicide film is formed on the surfaces of the dummy electrodes 11a and 11b. Although diffusion resistance and contact resistance can be lowered by forming the metal silicide layer 21 on the surfaces of the n⁺-type semiconductor regions 15 and p⁺-type semiconductor regions 16, the formation of the metal silicide layer 21 can be omitted if unnecessary.

Next, an insulating film 22 is formed on the semiconductor substrate 1. More specifically, the insulating film 22 is formed on the semiconductor substrate 1 so as to cover the dummy electrodes 11a and 11b. The insulating film 22 is formed of, for example, a silicon oxide film (for example, TEOS (Tetraethoxysilane) oxide film). When the temperature during the formation process of the insulating film 22 is relatively high, it is preferable to form a cobalt silicide layer as the above-mentioned metal silicide layer 21. On the contrary, when the formation temperature for the insulating film 22 is not so high, a nickel silicide layer can be used for the above-mentioned metal silicide layer 21.

Next, a planarization process on the upper surface of the insulating film 22 is performed through CMP (Chemical Mechanical Polishing) to expose the surfaces of the insulating films 7. Consequently, the structure shown in FIG. 5 can be obtained.

Next, as shown in FIG. 6, etching is performed to remove the insulating films 7 on the dummy electrodes 11a and 11b, thereby exposing the surfaces (upper surfaces) of the dummy electrodes 11a and 11b. The insulating films 7 on the dummy electrodes 11a and 11b can be removed through wet etching using diluted hydrofluoric acid and others. Further, since the thickness of the insulating film 22 is larger than that of the insulating film 7, even though the insulating films 7 on the dummy electrodes 11a and 11b are removed through etching, the insulating film 22 is left. Furthermore, by forming the sidewalls 14 of a material different from that of the insulating films 7, for example, by forming the insulating films 7 of silicon oxide and the sidewalls 14 of silicon nitride, it is possible to leave the sidewalls 14 even after the insulating films 7 on the dummy electrodes 11a and 11b are removed through etching.

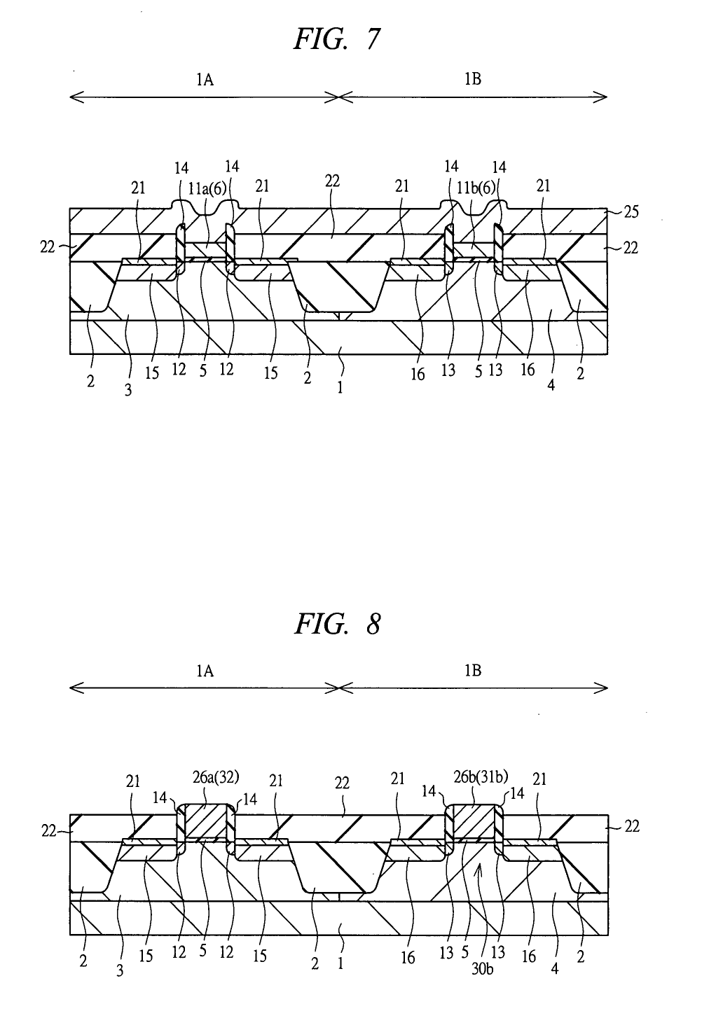

Next, as shown in FIG. 7, a metal film 25 made of the first metal is formed on the semiconductor substrate 1. More specifically, the metal film 25 is formed on the semiconductor substrate 1 (insulating films 22) including the upper surfaces on the dummy electrodes 11a and 11b. The metal film 25 can be formed through, for example, sputtering. As described above, since the metal film 25 is formed after the dummy electrodes 11a and 11b are exposed by removing the insulating films 7 on the dummy electrodes 11a and 11b, the metal film 25 is formed on the dummy electrodes 11a and 11b, and the upper surfaces of the dummy electrodes 11a and 11b formed of the silicon film 6 are in contact with the metal film 25.

The metal film 25 is a metal film containing a metal (first metal) having a work function higher than that of a metal which forms a metal film 35 described later, as its main constituent element. The metal film 25 is, for example, a metal film containing nickel (Ni) as its main constituent element, i.e., an Ni (nickel) film. As the material of the metal film 25, precious metals such as Pt (platinum), Ru (ruthenium), Ir (iridium) and Pd (palladium), and Co (cobalt) can be used other than nickel (Ni). The use of such metal elements to form the metal film 25 allows the silicidation reactions described later to occur easily, and the work function of the silicide to be formed (corresponding to metal silicide films 26a and 26b described later) can be increased.

After the metal film 25 is formed, as shown in FIG. 8, a heat treatment is performed to react the metal film 25 with the dummy electrodes 11a and 11b (silicon films 6), thereby forming metal silicide films (metal silicide layers or conductive films) 26a and 26b. More specifically, through the heat treatment, the silicon film 6 which forms the dummy electrode 11a of the n-channel type MISFET formation region 1A is reacted with the metal film 25 to form the metal silicide film 26a (dummy gate electrode 32), and the silicon film 6 which forms the dummy electrode 11b of the p-channel type MISFET formation region 1B is reacted with the metal film 25 to form the metal silicide film 26b (gate electrode 31b). The temperature of this heat treatment corresponds to a heat treatment temperature T₁ described below. For example, by performing a heat treatment in nitrogen gas atmosphere at about 400° C., the metal film 25 is reacted with the dummy electrodes 11a and 11b, thereby forming the metal silicide films 26a and 26b. In this case, whole silicon films 6 which form the dummy electrodes 11a and 11b are reacted with the metal film 25 to form the metal silicide films 26a and 26b. Thereafter, unreacted part of the metal film 25 is removed. For example, through SPM treatment (treatment using Sulfuric acid/hydrogen peroxide mixture: H₂SO₄/H₂O₂/H₂O) or the like, unreacted part of the metal film 25 can be removed. In this manner, the structure shown in FIG. 8 can be obtained.

In the above-described manner, the metal film 25 (Ni film in this case) and the silicon films 6 which form the dummy electrodes 11a and 11b are reacted to form the metal silicide films (nickel silicide films) 26a and 26b made of nickel silicide (Ni_{y}Siₓ) or the like. In other words, the metal silicide films 26a and 26b are both made of metal silicide (nickel silicide in this case) made from the reaction between the metal element (first metal: Ni in this case) which forms the metal film 25 and Si (silicon). Therefore, at this stage, the metal silicide film 26a and the metal silicide film 26b substantially have the same composition.

Of the metal silicide films 26a and 26b, the metal silicide film 26b formed in the p-channel type MISFET formation region 1B (i.e., the metal silicide film 26b formed by the reaction between the dummy electrode 11b and the metal film 25) becomes the gate electrode 31b of a p-channel type MISFET 30b. Since the gate electrode 31b of the p-channel type MISFET 30b is formed of the metal silicide film (nickel silicide film) 26b (which shows metallic conduction), it is a metal gate electrode. Also, of the metal silicide films 26a and 26b, the metal silicide film 26a formed in the n-channel type MISFET formation region 1A (i.e. the metal silicide film 26a formed by the reaction between the dummy electrode 11a and the metal film 25) becomes the dummy gate electrode 32 which is the pseudo gate electrode of the n-channel type MISFET 30a.

In this manner, the dummy gate electrode 32 of the n-channel type MISFET and the gate electrode 31b of the p-channel type MISFET 30b made of metal silicide (metal silicide films 26a and 26b) containing the first metal (Ni in this case) which forms the metal film 25 as its constituent element can be formed on the semiconductor substrate 1 with interposing the gate insulators 5 (insulating films for the gate insulators) therebetween.

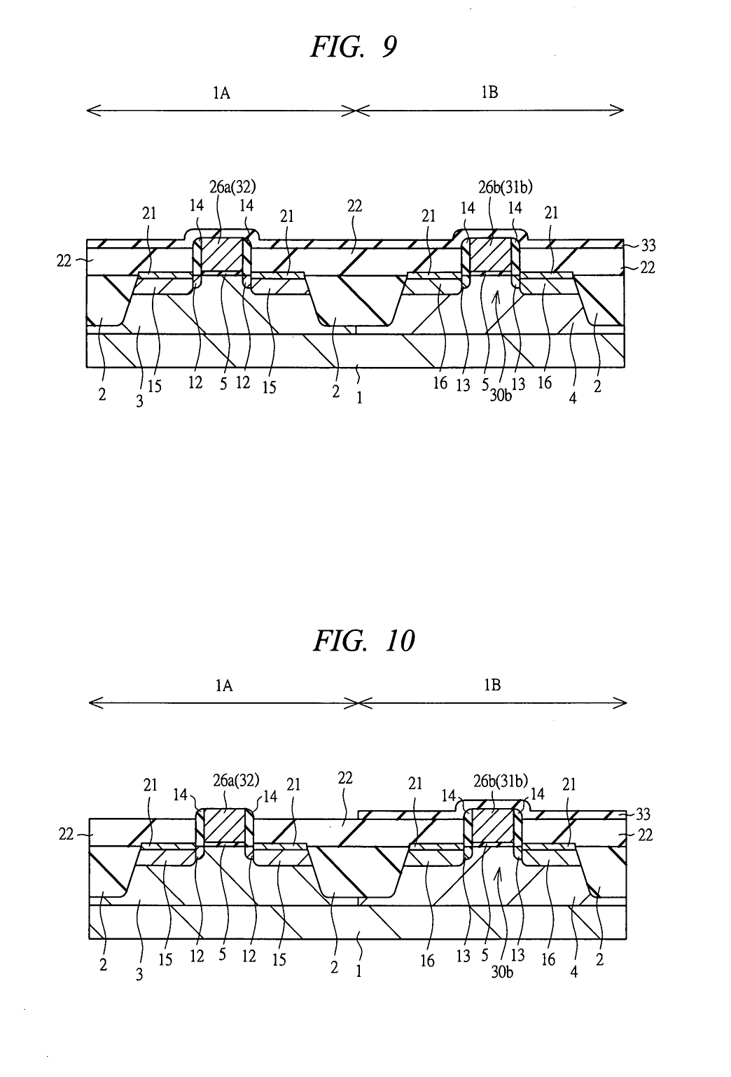

Next, as shown in FIG. 9, on the whole main surface of the semiconductor substrate 1 (on the insulating film 22 and the metal silicide films 26a and 26b), an insulating film 33 (first material film) made of silicon oxide or the like is formed (deposited). More specifically, the insulating film 33 (first material film) is formed on the semiconductor substrate 1 so as to cover the metal silicide films 26a and 26b (dummy gate electrode 32 and gate electrode 31b).

Next, as shown in FIG. 10, the insulating film 33 is patterned by photolithography or dry-etching, thereby forming the insulating film 33 which covers the p-channel type MISFET formation region 1B (gate electrode 31b) and exposes the n-channel type MISFET formation region 1A (dummy gate electrode 32). In other words, the insulating film 33 is patterned so that the insulating film 33 (in particular, the insulating film 33 on the dummy gate electrode 32) of the n-channel type MISFET formation region 1A is removed and the insulating film 33 (in particular, the insulating film 33 on the gate electrode 31b) of the p-channel type MISFET formation region 1B is left. By this means, the insulating film 33 which covers the gate electrode 31b of the p-channel type MISFET formation region 1B and exposes the dummy gate electrode 32 of the n-channel type MISFET formation region 1A is formed. As a result, although the metal silicide film 26b which is the gate electrode 31b of the p-channel type MISFET 30b is covered with the insulating film 33, the upper surface of the metal silicide film 26a which is the dummy gate electrode 32 of the n-channel type MISFET formation region 1A is exposed.

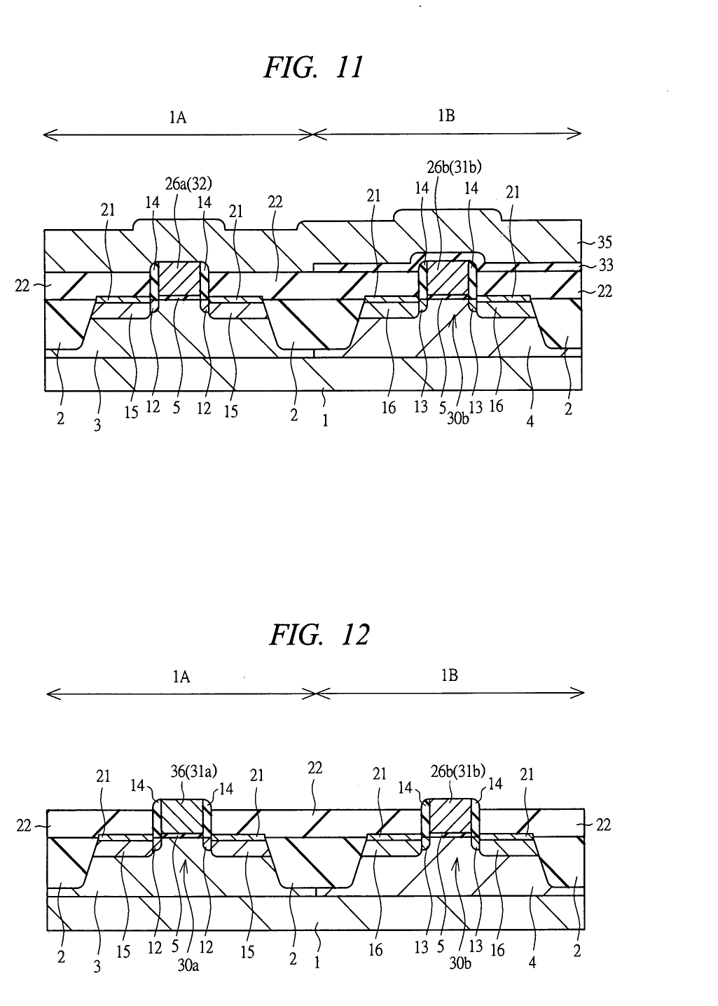

Next, as shown in FIG. 11, on the semiconductor substrate 1, the metal film (Al film) 35 formed of a second metal having a work function lower than that of the first metal (metal which forms the metal film 25) is formed. In other words, the metal film (Al film) 35 is formed on the insulating film 22 and the metal silicide film 26a of the n-channel type MISFET formation region 1A and the insulating film 33 of the p-channel type MISFET formation region 1B. As described above, since the metal film 35 is formed in a state where the metal silicide film 26b (gate electrode 31b) of the p-channel type MISFET 30b is covered with the insulating film 33 and the upper surface of the metal silicide film 26a of the n-channel type MISFET formation region 1A is exposed, the upper surface of the metal silicide film 26a (i.e., the dummy gate electrode 32) of the n-channel type MISFET formation region 1A contacts with the metal film 35, but the metal silicide film 26b (i.e., the gate electrode 31b) of the p-channel type MISFET formation region 1B does not contact with the metal film 35. The metal film 35 can be formed by using, for example, sputtering.

In this manner, the metal film 35 can be formed to contact with the dummy gate electrode 32 (metal silicide film 26a) of the n-channel type MISFET but not to contact with the gate electrode 31b (metal silicide film 26b) of the p-channel type MISFET.

The metal film 35 is made of a metal (i.e., the second metal) having a work function lower than that of the metal which forms the metal film 25 (i.e., the first metal). In other words, the work function of the metal (i.e., the second metal) which forms the metal film 35 is lower than that of the metal (i.e., the first metal) which forms the metal film 25. In addition, since the metal silicide films 26a and 26b (dummy gate electrode 32 and gate electrode 31b) are formed by the reaction between the metal film 25 made of the first metal and the silicon film 6, the metal silicide films 26a and 26b are formed of a metal silicide made from the first metal and Si (silicon) (i.e., meal silicide having the first metal as its constituent element). Therefore, in other words, the metal film 35 is formed of the second metal having a work function lower than that of the first metal which is a constituent element of the metal silicide films 26a and 26b (dummy gate electrode 32 and gate electrode 31b).

The metal film 35 is, for example, a metal film containing Al (aluminum) as its main component, i.e., an aluminum (Al) film. Other than aluminum (Al), a metal such as Hf (hafnium), Ti (titanium), Zr (zirconium), and Ta (tantalum) which have a work function lower than that of Ni (nickel) can be used for the main component of the metal film 35.

After the metal film 35 is formed, as shown-in FIG. 12, by performing a heat treatment, a conductive film 36 is formed by reacting the metal silicide film 26a (dummy electrode 32) of the n-channel type MISFET formation region 1A with the metal film 35. More specifically, through the heat treatment, the conductive film 36 is formed by reacting the metal silicide 26a which forms the dummy gate electrode 32 of the n-channel type MISFET formation region 1A with the metal film 35. The temperature of the heat treatment corresponds to a heat treatment temperature T₂ described later. For example, by performing a heat treatment in a nitrogen gas atmosphere at 400° C., the metal silicide film 26a (dummy gate electrode 32) of the n-channel type MISFET formation region 1A is reacted with the metal film 35, thereby forming the conductive film 36. In this heat treatment, since the metal silicide film 26b (gate electrode 31b) of the p-channel type MISFET formation region 1B and the metal film 35 are not in contact with each other because of the insulating film 33 interposed therebetween, the metal silicide film 26b which forms the gate electrode 31b of the p-channel type MISFET formation region 1B is not reacted with the metal film 35. Moreover, in this heat treatment, the insulating film 33 is not reacted with the metal silicide film 26b (gate electrode 31b) and the metal film 35.

Thereafter, unreacted part of the metal film 35 is removed. For example, through etching and/or CMP process, the unreacted part of the metal film 35 can be removed. As an etching solution for removing the unreacted part of the metal film 35, for example, in the case where the metal film 35 is Al, HNO₃/CH₃COOH/H₃PO₄ solution or the like can be used. In addition, in the same step for removing the unreacted part of the metal film 35 or a step thereafter, the insulating film 33 is removed. In this manner, the structure shown in FIG. 12 can be obtained.

Here, the insulating film 33 interposed between the metal silicide film 26b (gate electrode 31b) and the metal film 35 is a film provided to avoid the reaction therebetween at the time of the heat treatment. Therefore, any material film can be used for the insulating film 33 as long as it does not react with the metal silicide film 26b (gate electrode 31b) and the metal film 35 in the heat treatment process for reacting the metal silicide film 26a (dummy gate electrode 32) and the metal film 35, and insulating properties are not always necessary. Accordingly, as the insulating film 33, a conductive film may be used instead of an insulating film. However, when a conductive film is used instead of the insulating film 33, it is necessary to surely remove the conductive film after removing the unreacted part of the metal film 35. If there remains the conductive film used instead of the insulating film 33, the conductive film is present in the vicinity of the gate electrode 31b of the manufactured semiconductor device and it may pose a problem of deteriorating reliability of the semiconductor device. Accordingly, as shown in the present embodiment, it is more preferable to use the insulating film 33 having insulating properties. In this case, even if the insulating film 33 remains eventually, the insulating film 33 may not pose any adverse effect and it can further improve the reliability of the manufactured semiconductor device. Accordingly, when the insulating film 33 has insulating properties, it is possible to implement a process for forming an insulating film 41 described later without removing the insulating film 33 after the removing process for the unreacted part of the metal film 35.

As described above, by the reaction between the metal silicide film 26a (dummy gate electrode 32) of the n-channel type MISFET forming region 1A and the metal film 35 (Al film in this case), the second metal (aluminum (Al) in this case) which forms the metal film 35 diffuses into the metal silicide film 26a, and the metal silicide film 26a (dummy gate electrode 32) of the n-channel type MISFET formation region 1A becomes the conductive film 36 which contains the second metal (Al in this case). Since the metal silicide film 26a (dummy gate electrode 32) is made of a metal silicide formed of the first metal (Ni in this case) which is a metal element forming the metal film 25 and silicon (Si), the conductive film 36 is a conductive film formed of Si (silicon), the first metal (Ni in this case) which is the metal element forming the metal film 25, and the second metal (Al in this case) which is the metal element forming the metal film 35, and so it has metallic conductivity. The conductive film 36 becomes the gate electrode 31a of the n-channel type MISFET 30a. The gate electrode 31a of the n-channel type MISFET 30a is formed of the conductive film 36 having metallic conductivity, and therefore, it is a metal gate electrode.

In the above-described manner, it is possible to form the gate electrode 31a of the n-channel type MISFET 30a formed of the conductive film 36 containing Si, the first metal (Ni in this case) and the second metal (Al in this case) as its constituent elements.

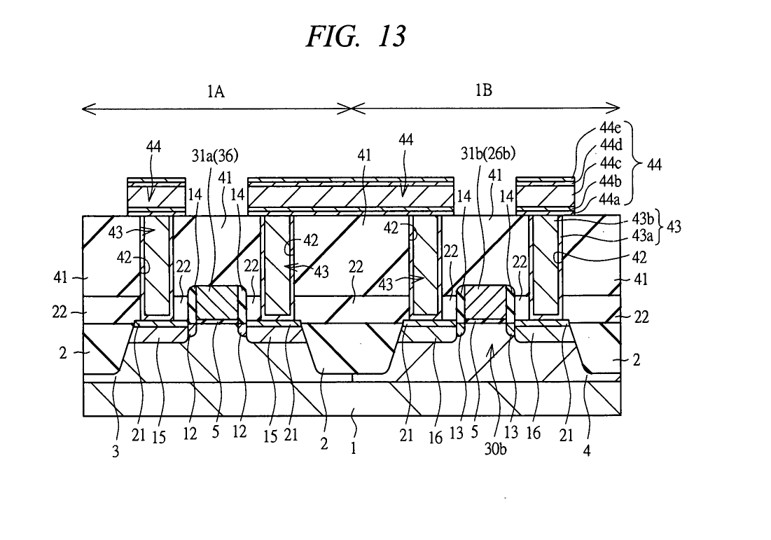

Next, as shown in FIG. 13, an insulating film 41 is formed on the semiconductor substrate 1. More specifically, the insulating film (interlayer insulating film) 41 is formed on the semiconductor substrate 1 (insulating film 22) so as to cover the gate electrodes 31a and 31b. The insulating film 41 is formed of, for example, a silicon oxide film (TEOS oxide film, for example). Thereafter, an upper surface of the insulating film 41 is planarized through CMP or the like if needed.

Next, the dry etching is performed to the insulating film 41 and the insulating film 22 with using a photoresist pattern (not shown) formed on the insulating film 41 through photolithography as an etching mask. By this means, contact holes (openings) 42 are formed on (above) the n⁺-type semiconductor regions 15 (source and drain), the p⁺-type semiconductor regions 16 (source and drain), the gate electrodes 31a and 31b and others. At the bottom of the contact hole 42, a part of the upper surface of the semiconductor substrate 1, for example, a part of the n⁺-type semiconductor region 15 (or the metal silicide layer 21 on the surface thereof), a part of p⁺-type semiconductor region 16 (or the metal silicide layer 21 on the surface thereof), or a part of the gate electrodes 31a and 31b is exposed. Note that, in the cross-sectional view of FIG. 13, a part of the n⁺-type semiconductor region 15 (or the metal silicide layer 21 on the surface thereof) and a part of the p⁺-type semiconductor region 16 (or the metal silicide layer 21 on the surface thereof) are exposed at the bottoms of the contact holes 42. However, by forming the contact holes 42 on the gate electrodes 31a and 31b at any region (section) not shown, a part of the gate electrodes 31a and 31b can be exposed at the bottoms of the contact holes 42.

Next, a plug 43 made of tungsten (W) or the like is formed in the contact hole 42. For example, the plug 43 can be formed through the steps of: forming a barrier film (titanium nitride, for example) 43a on the insulating film 41 including the inside of the contact holes 42; forming a tungsten film 43b on the barrier film 43a though CVD or the like so as to fill the contact holes 42; and removing unnecessary part of the tungsten film 43b and the barrier film 43a on the insulating film 41 thorough CMP or etch-back process.

Next, an interconnect (first interconnect layer) 44 is formed on the insulating film 41 in which the plug 43 is embedded. For example, a titanium film 44a, a titanium nitride film 44b, an aluminum film 44c, a titanium film 44d, and a titanium nitride film 44e are sequentially formed through sputtering or the like, and they are patterned through photolithography or dry-etching. By this means, the interconnect 44 can be formed. The aluminum film 44c is a conductive film containing single aluminum (Al) or an aluminum alloy as its main element. The interconnect 44 is electrically connected via the plug 43 to the n⁺-type semiconductor region 15 for the source or drain of the n-channel type MISFET 30a, the p⁺-type semiconductor region 16 for the source or drain of the p-channel type MISFET 30b, the gate electrode 31a of the n-channel type MISFET 30a, the gate electrode 31b of the p-channel type MISFET 30b, or the like. The interconnect 44 is not limited to the aluminum interconnect as described above but can be modified into various forms, and it can be a tungsten interconnect or a copper interconnect (for example, a buried copper interconnect formed by damascene process). Although an interlayer insulating film and upper interconnect layers are further formed thereafter, the description thereof is omitted here. A second layer interconnect and the following interconnect can be formed as buried copper interconnects formed through damascene process.

The semiconductor device manufactured in the above-described manner according to the present embodiment has a CMISFET including the n-channel type MISFET 30a and the p-channel type MISFET 30b formed on the main surface of the semiconductor substrate 1, and the gate electrodes 31a and 31b of the MISFETs 30a and 30b are metal gate electrodes formed of the metal silicide film 26b and the conductive film 36, respectively.

As described above, the gate electrode 31b (i.e., the metal silicide film 26b) of the p-channel type MISFET 30b is formed by the reaction between the metal film 25 (Ni film in this case) and the silicon film 6 (dummy gate electrode 11b). Therefore, the gate electrode 31b of the p-channel type MISFET 30b is made of a metal silicide containing the first metal (Ni in this case) and silicon (Si) as its constituent elements, that is, it is made of nickel silicide (Ni_{y}Siₓ: x>0, y>0). In addition, it is more preferable that a rate of the metal (first metal) in the metal silicide which forms the gate electrode 31b (i.e., metal silicide film 26b) of the p-channel type MISFET 30b (rate of nickel (Ni) in nickel silicide in this case) is larger than a rate of silicon (Si) thereof (i.e., y>x for Ni_{y}Siₓ).

On the other hand, as described above, the gate electrode 31a (i.e., the conductive film 36) of the n-channel type MISFET 30a is formed by reacting an Ni film (metal film 25) with the silicon film 6 (dummy electrode 11a) to form the metal silicide film 26a and further reacting the metal silicide film 26a with the metal film 35 (Al film in this case). Accordingly, the gate electrode 31a (i.e., the conductive film 36) of the n-channel type MISFET 30a is a conductive film containing the first metal (Ni in this case) which forms the metal film 25, the second metal (Al in this case) which forms the metal film 35, and silicon (Si) as its constituent elements, and it is, for example, a metal silicide film (nickel silicide film in this case) in which aluminum (Al) is introduced or diffused. In other words, the gate electrode 31a (conductive film 36) of the n-channel type MISFET 30a is formed of a conductive film obtained by introducing or diffusing a second metal (Al in this case) into a metal silicide (nickel silicide in this case) containing a first metal (Ni in this case). Note that the second metal (Al in this case) has a work function lower than that of the first metal (Ni in this case).

Next, the effects obtained by the present embodiment will be described in more detail.

The gate electrode 31b (i.e. the metal silicide film 26b) of the p-channel type MISFET 30b is formed of metal silicide containing the first metal (Ni in this case) as its constituent element such as nickel silicide (Ni_{y}Siₓ), and its work function is about 4.65 eV when the first metal is Ni and the ratio of Ni and Si is approximately equal (i.e. y≈x in Ni_{y}Siₓ). As the ratio of the first metal (Ni in this case) is increased, the work function of the metal silicide (nickel silicide (Ni_{y}Siₓ) in this case) can be gradually increased to about 4.8 eV. Therefore, the work function of the gate electrode 31b (i.e. the metal silicide film 26b) of the p-channel type MISFET 30b can be set to approximately 4.65 to 4.8 eV by adjusting the ratio of the first metal which forms the metal silicide, for example, the ratio (y/x) of nickel (Ni) in nickel silicide (Ni_{y}Siₓ). Further, the ratio of the first metal of the metal silicide (ratio of nickel (Ni) of nickel silicide (Ni_{y}Siₓ)) which forms the gate electrode 31b (i.e., metal silicide film 26b in this case) of the p-channel type MISFET 30b can be controlled by adjusting the deposition thickness of the metal film 25 (Ni film) and the temperature of the heat treatment for the reaction between the silicon film 6 and the metal film 25 (Ni film). Still further, when the above-mentioned first metal is Pt (platinum), the work function of the gate electrode 31b (i.e. the metal silicide film 26b) of the p-channel type MISFET 30b can be set to about 4.9 to 5.0 eV by adjusting the ratio of Pt (y/x) of platinum silicide (Pt_{y}Siₓ).

On the other hand, the gate electrode 31a of the n-channel type MISFET 30a is formed of the conductive film 36 formed by reacting the metal silicide film 26a (nickel silicide film: Ni_{y}Siₓ film in this case) with the metal film 35 (aluminum film). Accordingly, since the second metal (Al) having a work function lower than the first metal (Ni in this case) is introduced, the work function of the conductive film 36 which forms the gate electrode 31a of the n-channel type MISFET 30a is reduced to, for example, about 4.2 to 4.3 eV, which is lower than that of the metal silicide films 26a and 26b (nickel silicide films: Ni_{y}Siₓ films in this case).

More specifically, the metal silicide films 26a and 26b are formed by reacting a silicon film with the metal film 25 made of the first metal (Ni in this case) having a high work function, and the silicide film 26b thus formed is used to form the gate electrode 31b of the p-channel type MISFET. By this means, the work function of the gate electrode 31b of the p-channel type MISFET 30b is increased. By increasing the work function of the gate electrode 31b of the p-channel type MISFET 30b, (the absolute value of) the threshold voltage of the p-channel type MISFET 30b can be lowered.

Further, the metal silicide film 26a and the metal film 35 made of the second metal (Al in this case) having a low work function (lower than that of the above-mentioned first metal) are reacted to form the conductive film 36, and the conductive film 36 thus formed is used to form the gate electrode 31a of the n-channel type MISFET 30a. By this means, the work function of the gate electrode 31a of the n-channel type MISFET 30a is made lower than that of the gate electrode 31b of the p-channel type MISFET 30b. For example, the work function of the gate electrode 31a (conductive film 36) of the n-channel type MISFET 30a can be made lower than that of the gate electrode 31b (metal silicide film 26b) of the p-channel type MISFET 30b by approximately 0.4 eV. For example, in the case where the work function of the gate electrode 31b (metal silicide film 26b) of the p-channel type MISFET 30b is 4.65 eV, the work function of the gate electrode 31a (conductive film 36) of the n-channel type MISFET 30a can be set to about 4.2 to 4.3 eV, which is a value lower than 4.65 eV by about 0.4 eV. By decreasing the work function of the gate electrode 31a of the n-channel type MISFET 30a, (the absolute value of) the threshold voltage of the n-channel type MISFET 30a can be lowered.

In this manner, it is possible to lower the threshold voltage in both the n-channel type MISFET 30a and the p-channel type MISFET 30b of the CMISFET, and thus, the performance of a semiconductor device having the CMISFET can be improved.

Further, it is more preferable that the ratio of the metal (i.e. the first metal, Ni in this case) in the metal silicide film 26b which forms the gate electrode 31b of the p-channel type MISFET 30b is made larger than that of Si (silicon). By this means, the work function of the gate electrode 31b (metal silicide film 26b) of the p-channel type MISFET 30b can be further increased to 4.8 eV. In this manner, the work function of the gate electrode 31a (conductive film 36) of the n-channel type MISFET 30a can be set to about 4.4 eV, which is lower than that of the gate electrode 31b of the p-channel type MISFET 30b by 0.4 eV. Therefore, the gate electrodes 31a and 31b having work functions with good symmetry based on the midgap can be accurately formed, and a semiconductor device including a CMISFET having threshold voltages with good symmetry can be realized.

In addition, different from the present embodiment, in the case where the metal film is directly formed on the gate insulator 5 thorough sputtering or the like, there is a possibility that the gate insulator 5 is damaged. On the other hand, in the present invention, the silicon film 6 is formed on the gate insulator 5 through CVD or the like, and the metal silicide films 26a and 26b are formed by reacting the silicon film 6 with the metal film 25 formed thereon. Then, the conductive film 36 is formed by reacting the metal silicide film 26a with the metal film 35. In this manner, the gate electrode 31a (conductive film 36) and the gate electrode 31b (metal silicide film 26b) are formed as the metal gate electrodes. Therefore, the damages applied onto the gate insulators 5 can be prevented.

Further, different from the present invention, in the case where the source/drain regions are formed after the metal gate electrode is formed, there is the possibility that, by the annealing process at high temperature (activation annealing) to activate impurities introduced into the source/drain regions through ion-implantation, the metal which forms the gate electrode is reacted with the gate insulator, the gate electrode is exfoliated from the gate insulator, or the metal atoms of the gate electrode are diffused into the gate insulator and further into the silicon substrate, and as a result, the electric characteristics of the MISFET are deteriorated. On the other hand, in the present embodiment, after the annealing to activate the impurities introduced (ion-implanted) into the source/drain regions (n⁻-type semiconductor regions 12, p⁻-type semiconductor regions 13, n⁺-type semiconductor regions 15, and p⁺-type semiconductor regions 16) is performed, the metal silicide films 26a and 26b are formed by reacting the silicon films 6 (dummy electrodes 11a and 11b) with the metal film 25 formed thereon. Therefore, it is possible to prevent the reaction between the gate electrode and the gate insulator, the exfoliation of the gate electrode from the gate insulator, and the diffusion of the metal atoms into the gate insulator and silicon substrate in the annealing process to activate the impurities, and thus, it is possible to prevent the degradation of electric characteristics of the MISFET.

Still further, in the present embodiment, after forming the dummy electrodes 11a and 11b formed of the silicon film 6, the metal silicide films 26a and 26b are formed by reacting the dummy electrodes 11a and 11b with the metal film 25, and the conductive film 36 is formed by further reacting the metal silicide film 26a with the metal film 35. In this manner, the gate electrode 31a (conductive film 36) and the gate electrode 31b (metal silicide film 26b) are formed. Therefore, it is possible to use the existing manufacturing line and the manufacturing apparatus for the semiconductor devices having conventional polysilicon gate structure, and the semiconductor devices having the metal gate structure can be manufactured easily at low cost.

In addition, in the present embodiment, after forming the metal silicide films 26a and 26b, the metal film 35 is formed so that it contacts with the metal silicide film 26a but not contact with the metal silicide film 26b. In the present embodiment, after the insulating film 33 is formed so as to cover the p-channel type MISFET formation region 1B and expose the n-channel type MISFET formation region 1A as shown in FIG. 10, the metal film 35 is formed as shown in FIG. 11. Therefore, the insulating film 33 is interposed between the metal film 35 and the metal silicide film 26b, thereby obtaining the structure where the metal film 35 contacts with the metal silicide film 26a but not with the metal silicide film 26b. Then, by performing the heat treatment thereto, the metal silicide film 26a (dummy gate electrode 32) of the n-channel type MISFET formation region 1A and the metal film 35 in contact with each other are reacted, thereby forming the conductive film 36. Meanwhile, the metal silicide film 26b (gate electrode 31b) of the p-channel type MISFET 30b is not reacted with the metal film 35 because the insulating film 33 is interposed therebetween. By this means, the second metal (Al in this case) having a work function lower than that of the first metal (Ni in this case) which forms the metal silicide film 26a is introduced into the metal silicide 26a of the n-channel type MISFET formation region 1A, thereby forming the conductive film 36. Meanwhile, any metal element (Al in this case) other than the first metal (Ni in this case) which forms the metal silicide film 26b is not introduced into the metal silicide film 26b of the p-channel type MISFET 30b.

Different from the present embodiment, it is considerable that the gate electrode of the n-channel type MISFET to which aluminum (Al) is introduced (corresponding to the gate electrode 31a) and the gate electrode of the p-channel type MISFET formed of nickel silicide (corresponding to the gate electrode 31b) are formed separately, but it may increase the number of processes to manufacture the semiconductor device. For example, it is required that, after selectively covering the n-channel type MISFET formation region 1A with a cap insulating film, a gate electrode made of nickel silicide for a p-channel type MISFET (corresponding to the gate electrode 31b) is formed, and then, after selectively covering the p-channel type MISFET formation region 1B with another cap insulating film, an Al-replacement process of the gate electrode is performed in the n-channel type MISFET formation region 1A. This may increase the number of processes to manufacture the semiconductor device, and the cost of manufacturing a semiconductor device is increased and the manufacturing yield thereof is lowered.

On the contrary, in the present embodiment, the dummy electrodes 11a and 11b are reacted with the metal film 25 (Ni film) in both the n-channel type MISFET formation region 1A and the p-channel type MISFET formation region 1B to form the metal silicide films 26a and 26b formed of the same material. Therefore, there is no need to selectively cover only the n-channel type MISFET formation region 1A with a cap insulating film and others before forming the metal silicide films 26a and 26b. Accordingly, the number of manufacturing processes of the semiconductor device can be reduced.

Further, in the present embodiment, after the metal silicide films 26a and 26b are formed, the p-channel type MISFET formation region 1B is selectively covered with the insulating film 33, and then, the metal film 35 (Al film) is formed. Thereafter, the metal film 35 and the metal silicide film 26a in the n-channel type MISFET formation region 1A are reacted with each other to form the gate electrode 31a of the n-channel type MISFET 30a to which the second metal (Al in this case) with a low work function is introduced. Therefore, the second metal (Al in this case) with low work function which forms the metal film 35 is introduced to the gate electrode 31a of the n-channel type MISFET 30a, but the second metal (Al in this case) with low work function which forms the metal film 35 is not introduced to the gate electrode 31b of the p-channel type MISFET 30b formed of the metal silicide film 26b which is not reacted with the metal film 35 (Al film). Consequently, the gate electrode 31b of the p-channel type MISFET 30b is formed from the metal silicide film 26b (nickel silicide film) with high work function, and by introducing the second metal (Al in this case) which is a metal element with a low work function and forms the metal film 35, the gate electrode 31a of the n-channel type MISFET 30a is formed from the conductive film 36 with low work function. Therefore, it becomes possible to lower the threshold voltages of both the n-channel type MISFET 30a and the p-channel type MISFET 30b of the CMISFET while suppressing the number of manufacturing processes of the semiconductor device.

As described above, in the present embodiment, the dummy electrodes 11a and 11b are reacted with the metal film 25 (Ni film) to form the metal silicide films 26a and 26b in both the n-channel type MISFET formation region 1A and the p-channel type MISFET formation region 1B, and then only the metal silicide film 26a is reacted with the metal film 35 (Al film), thereby separately forming the gate electrode 31a of the n-channel type MISFET 30a and the gate electrode 31b of the p-channel type MISFET 30b. Consequently, it is possible to satisfy both of performance improvement of a semiconductor device having a CMISFET (reduction in threshold voltages of both the n-channel type MISFET 30a and the p-channel type MISFET 30b of the CMISFET) and reduction in the manufacturing cost (reduction in the number of manufacturing processes).

In addition, in the present embodiment, the gate electrode 31b of the p-channel type MISFET 30b is formed from the metal silicide film 26b which is formed by reacting the metal film 25 made of the first metal with the silicon film 6. Therefore, the metal silicide film 26b is required to have a high effective work function proper to the gate electrode of the p-channel type MISFET. Consequently, it is preferable that at least one of the materials selected from a group of Ni (nickel), Pt (platinum), Ru (ruthenium), Ir (iridium), Pd (palladium), and Co (cobalt) is used for the first metal to form the metal film 25 (i.e., the first metal which is a constituent element of the metal silicide film 26b). It is more preferable when Ni (nickel) or Pt (platinum) is used, and it is further preferable when Ni (nickel) is used.

Further, when a metal film containing Ni as its main component (Ni film) is used for the metal film 25, the full silicidation can be achieved by the heat treatment at a relatively low temperature. More specifically, it is possible to relatively reduce the heat treatment temperature in the heat treatment process for forming the metal silicide films 26a and 26b by reacting the silicon film 6 (dummy electrode 11a and 11b) with the metal film 25. Also, since the whole of the silicon film 6 which forms the dummy electrodes 11a and 11b can be reacted with the metal film 25 to form the metal silicide films 26a and 26b, it is possible to prevent the unreacted silicon film 6 from being left on the gate insulators 5. Further, reaction of the gate insulator 5 with the semiconductor substrate 1 and reaction of the gate insulator 5 with the silicon film 6 in the heat treatment can be suppressed or prevented. Accordingly, performance and reliability and the like of the semiconductor devices can be improved.

Still further, the gate electrode 31a of the n-channel type MISFET 30a is formed from the conductive film 36 obtained by reacting the metal silicide film 26a having the first metal as its constituent element with the metal film 35 formed of the second metal. Therefore, the conductive film 36 having the first and second metals and silicon as its constituent elements is required to have a low effective work function proper to the gate electrode of the n-channel type MISFET (work function lower than that of the gate electrode of the p-channel type MISFET). Consequently, the second metal which is a metal element forming the metal film 35 is required to have a work function lower than that of the above-mentioned first metal (i.e., a metal element forming the metal film 25 and a metal element which is the constituent elements of the metal silicide film 26b). Therefore, it is preferable that at least one of the materials selected from a group of, Al (aluminum), Hf (hafnium), Ti (titanium), Zr (zirconium), and Ta (tantalum) is used for the second metal which forms the metal film 35. It is more preferable if Al (aluminum) is used. The reason why it is more preferable when the metal film 35 is a metal film having aluminum (Al) as its main component, that is, an aluminum (Al) film is as follows.

That is, when the heat treatment temperature T₂ to react the metal silicide film 26a with the metal film 35 is high (for example, higher than 600° C.), during the heat treatment, NiSi₂ is formed in the metal silicide film 26b of the p-channel type MISFET formation region 1B, and it may lower the work function of the gate electrode 31b of the p-channel type MISFET 30b formed from the metal silicide film 26b. This works to increase (the absolute value of) the threshold voltage of the p-channel type MISFET 30b.

On the contrary, in the present embodiment, by using an aluminum (Al) film as the metal film 35, the heat treatment temperature T₂ to react the metal silicide film 26a with the metal film 35 to form the conductive film 36 can be reduced to be preferably equal to or lower than 600° C. (i.e., T₂≦600° C.). Consequently, the reaction (formation of NiSi₂) in the metal silicide film 26b in the p-channel type MISFET formation region 1B in the heat treatment process to react the metal silicide film 26a with the metal film 35 can be suppressed or prevented. By this means, it is possible to prevent lowering of the work function of the gate electrode 31b of the p-channel type MISFET 30b formed from the metal silicide film 26b. Therefore, (the absolute value of) the threshold voltage of the p-channel type MISFET 30b can be adequately lowered, and it is possible to adequately lower the threshold voltage of a CMISFET.

In addition, it is preferable that the heat treatment temperature T₂ to react the metal silicide film 26a with the metal film 35 is equal to or lower than a temperature which is 200° C. higher than the heat treatment temperature T₁ to react the dummy electrodes 11a and 11b (silicon films 6) with the metal film 25 (i.e., T₂≦T₁+200° C.). It is more preferable that the T₂ is equal to or lower than a temperature which is 100° C. higher than the heat treatment temperature Ti to react the dummy electrodes 11a and 11b (silicon films 6) with the metal film 25 (i.e., T₂≦T₁+100° C.). By this means, the further reaction (formation of NiSi₂) of the metal silicide film 26b in the p-channel type MISFET formation region 1B formed by the heat treatment at the heat treatment temperature T₁ in the heat treatment to react the metal silicide 26a with the metal film 35 performed at the heat treatment temperature T₂ can be adequately suppressed or prevented. Therefore, it is possible to prevent the work function of the gate electrode 31b of the p-channel type MISFET 30b formed from the metal silicide film 26b from being lowered, and (the absolute value of) the threshold voltage of the p-channel type MISFET 30b can be adequately lowered. Consequently, it is possible to adequately lower the threshold voltage of a CMISFET.

Further, it is preferable that the heat treatment temperature T₁ to react the dummy electrodes 11a and 11b (silicon films 6) with the metal film 25 is equal to or higher than 300° C. (T₁≧300° C.). In this manner, the whole of the dummy electrodes 11a and 11b can be reacted with the metal film 25 to form the metal silicide films 26a and 26b, and it is possible to prevent the silicon films 6 which form the dummy electrodes 11a and 11b from being left in an unreacted state. Still further, it is preferable that the heat treatment temperature T₂ to react the metal silicide film 26a with the metal film 35 is equal to or higher than 300° C. (T₂≧300° C.). In this manner, the reaction between the metal silicide film 26a and the metal film 35 is accelerated so that the second metal which forms the metal film 35 can be introduced more easily into the gate electrode 31a (conductive film 36).

Moreover, an aluminum (Al) film is easily reacted with a single film of nickel (Ni) (nickel film) but is not easily reacted with a single film of silicon (Si) (silicon film). Therefore, it is difficult to form aluminum silicide. Accordingly, even if it is intended to form a gate electrode to which aluminum is introduced (aluminum silicide gate electrode) by performing a heat treatment after forming an aluminum film on a silicon film in a manner different from the present embodiment, it is difficult to form the aluminum silicide gate electrode.

On the contrary, in the present embodiment, after once the metal silicide films 26a and 26b are formed, the metal silicide film 26a of these is reacted with the metal film 35 (Al film) to introduce aluminum to form the gate electrode 31a of the n-channel type MISFET 30a having lower work function. Compared to the case where a silicon film and an aluminum film are reacted with each other, the reaction easily occurs in the case where a metal silicide and aluminum are reacted with each other. More particularly, the reaction easily occurs in the case where nickel silicide containing nickel and aluminum are reacted with each other. Therefore, compared to the case where a silicon film and an aluminum film are reacted with each other, the reaction by the heat treatment proceeds more easily in the case where the metal film 35 (Al film) and the metal silicide film 26a are reacted with each other according to the present embodiment. Consequently, it is possible to more adequately form the gate electrode 31a of the n-channel type MISFET 30a in which the work function is lowered by introducing aluminum.

Further, in the present embodiment, after the metal silicide film 26a which is easily reacted with the metal film 35 (Al film) is formed, the metal silicide film 26a is reacted with the metal film 35 (Al film). Therefore, it is possible to lower the heat treatment temperature to form the gate electrode 31a of the n-channel type MISFET 30a (heat treatment temperature to react the metal silicide film 26a with the metal film 35), and it is possible to suppress or prevent the reaction (formation of NiSi₂) in the metal silicide film 26b which forms the gate electrode 31b of the p-channel type MISFET 30b during the heat treatment. Consequently, (the absolute value of) the threshold voltages of the n-channel type MISFET 30a and the p-channel type MISFET 30b can be more adequately lowered, and the threshold voltage of a CMISFET can be more adequately lowered.

In addition, the inventors of the present invention have confirmed that the work function (flatband voltage) of the gate electrode 31a formed in the manner of the present embodiment is lower than the work function (flatband voltage) of the gate electrode 31b by the examination as follows.

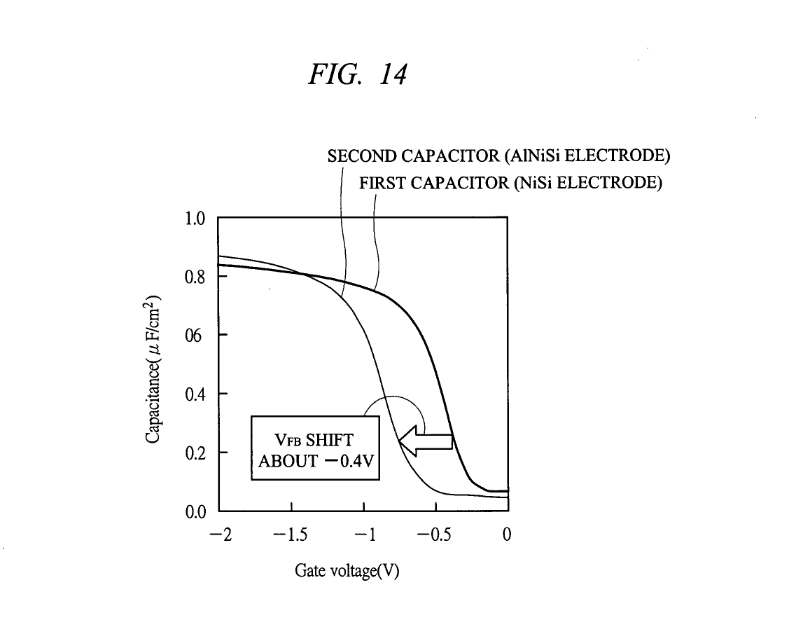

That is, after forming a silicon oxide film (corresponding to the gate insulator 5) on a semiconductor substrate made of p-type monocrystalline silicon (corresponding to the semiconductor substrate 1), a polycrystalline silicon film (corresponding to the silicon film 6) and an Ni film (corresponding to the metal film 25) are formed thereon. Then, a heat treatment at about 400° C. is performed to react the polycrystalline silicon film with the Ni film to form an NiSi electrode (corresponding to the gate electrode 31b made of nickel silicide), and a first capacitor (MOS capacitor) is formed. The first capacitor (MOS capacitor) is formed from the semiconductor substrate, the silicon oxide film, and the NiSi electrode. Thereafter, after an Al film (corresponding to the metal film 35) is formed, the NiSi electrode is reacted with the Al film by performing a heat treatment at about 400° C. to form an AlNiSi electrode (corresponding to the gate electrode 31a obtained by introducing Al by reacting nickel silicide with Al), and a second capacitor (MOS capacitor) is formed. The second capacitor (MOS capacitor) is formed from the semiconductor substrate, the silicon oxide, and the AlNiSi electrode. FIG. 14 is a graph showing C-V characteristics of the first and second capacitors (MOS capacitors) which are formed in the manner described above. The horizontal axis in FIG. 14 corresponds to the voltage to be applied to the NiSi electrode and the AlNiSi electrode of the first and second capacitors (MOS capacitors), and the vertical axis in FIG. 14 corresponds to the capacitance of the first and second capacitors.

As shown in the graph of FIG. 14, the C-V characteristic of the second capacitor (MOS capacitor) having the AlNiSi electrode is shifted from the C-V characteristic of the first capacitor (MOS capacitor) having the NiSi electrode. According to the analysis result of the C-V characteristics, it is confirmed that the flatband voltage V_{FB} of the AlNiSi electrode of the second capacitor is about 0.4 V (0.4 eV) lower than that of the NiSi electrode of the first capacitor (about −0.3 V) (i.e., the flatband voltage V_{FB} of the AlNiSi electrode of the second capacitor is about −0.7 V). This is probably because the work function of the AlNiSi electrode becomes lower than that of the NiSi electrode by introducing Al.

Almost similar to the gate electrode 31b of the present embodiment, the NiSi electrode of the first capacitor is formed by reacting the silicon film (corresponding to the silicon film 6) with the Ni film (corresponding to the metal film 25), and it is made of nickel silicide (corresponding to the metal silicide film 26b). Also, almost similar to the gate electrode 31a of the present embodiment, the AlNiSi electrode of the second capacitor is formed of a conductive film (corresponding to the conductive film 36) formed by reacting nickel silicide (corresponding to the metal silicide film 26a) with the Al film (corresponding to the metal film 35). Therefore, the fact that the flatband voltage of the AlNiSi electrode of the second capacitor is 0.4 eV lower than that of the NiSi electrode of the first capacitor suggests that the work function (flatband voltage) of the gate electrode 31a of the present embodiment is about 0.4 eV (0.4 V) lower than the work function (flatband voltage) of the gate electrode 31b of the present embodiment.

Consequently, in the CMISFET formed according to the present embodiment, the flatband voltage of the gate electrode 31a of the n-channel type MISFET 30a can be made 0.4 V lower than that of the gate electrode 31b of the p-channel type MISFET 30b. Therefore, the work function of the gate electrode 31b of the p-channel type MISFET 30b can be increased and the work function of the gate electrode 31a of the n-channel type MISFET 30a can be lowered, and it is possible to lower the threshold voltage in both the n-channel type MISFET 30a and the p-channel type MISFET 30b. Further, a CMISFET having threshold voltages with good symmetry can be realized.

### Second Embodiment

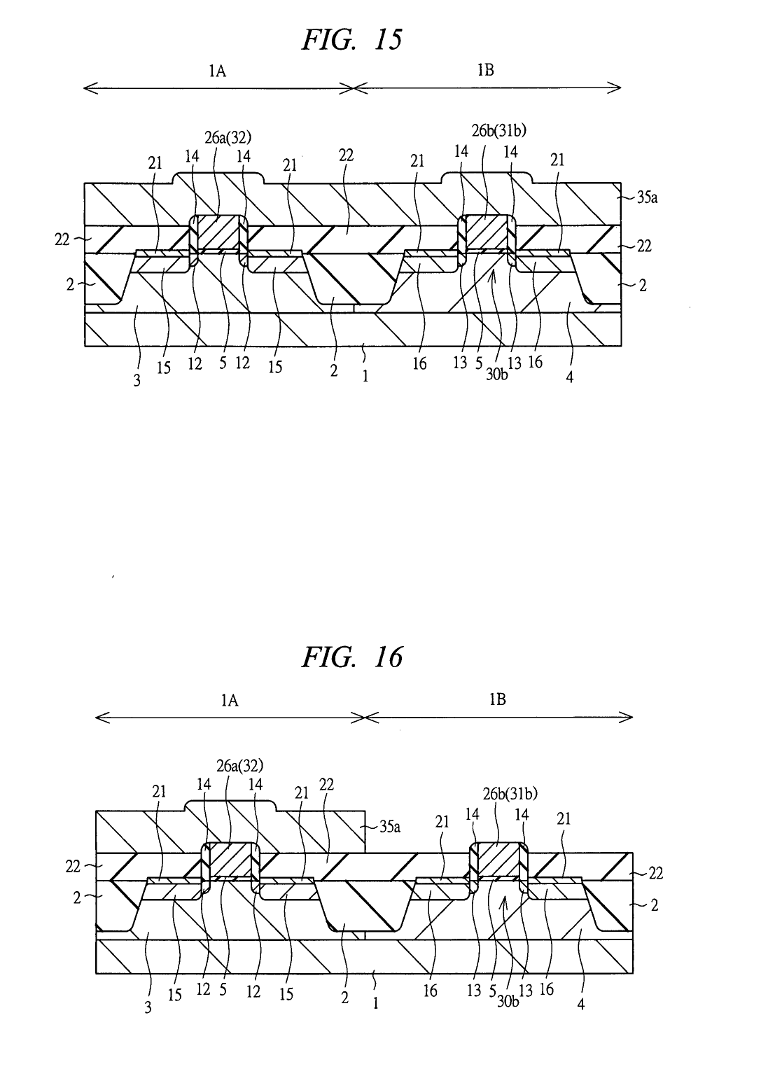

FIG. 15 to FIG. 18 are cross-sectional views of main parts of a semiconductor device in manufacturing processes according to another embodiment of the present invention. Since the processes until FIG. 8 are the same as those of the first embodiment, the repetitive description thereof is omitted and a description about the manufacturing processes continued from FIG. 8 is made here.

Different from the above-described first embodiment, after the structure of FIG. 8 is obtained in the same manner as the above-described first embodiment, as shown in FIG. 15, a metal film 35a made of the same material as the above-described metal film 35 is formed on the entire surface of the main surface of the semiconductor substrate 1 without forming the insulating film 33 (i.e., on the insulating film 22 and the metal silicide films 26a and 26b) in the same manner (e.g., through sputtering). More specifically, the metal film 35a is formed on the semiconductor substrate 1 so as to cover the metal silicide films 26a and 26b (dummy gate electrode 32 and gate electrode 31b).

Subsequently, as shown in FIG. 16, the metal film 35a is patterned through photolithography and dry-etching so that the metal film 35a in the p-channel type MISFET formation region 1B (particularly, the metal film 35a on the gate electrode 31b) is removed and the metal film 35a in the n-channel type MISFET formation region 1A (particularly, the metal film 35a on the dummy gate electrode 32) is left. By this means, the metal film 35a on the gate electrode 31b is removed and the metal film 35a on the dummy gate electrode 32 is left. In this manner, the metal film 35a is formed so as to contact with the dummy gate electrode 32 of the n-channel type MISFET but not to contact with the gate electrode 31b of the p-channel type MISFET. Thus, the metal film 35a is selectively formed in the n-channel type MISFET formation region 1A.

The metal film 35a is formed on the insulating film 22 and the metal silicide film 26a in the n-channel type MISFET formation region 1A. Meanwhile, since it is not formed in the p-channel type MISFET formation region 1B, the upper surface of the metal silicide film 26a in the n-channel type MISFET formation region 1A contacts with the metal film 35a, but the metal silicide film 26b (gate electrode 31b) of the p-channel type MISFET formation region 1B does not contact with the metal film 35a. The metal film 35a is made of the same material as the metal film 35 in the first embodiment, that is, it is made of the second metal having a work function lower than that of the first metal in the same manner as that of the first embodiment. More preferably, the metal film 35a is made of aluminum (Al). The materials applicable to the metal film 35a other than aluminum (Al) are the same as those of the metal film 35 in the first embodiment. Therefore, the description thereof is omitted here.

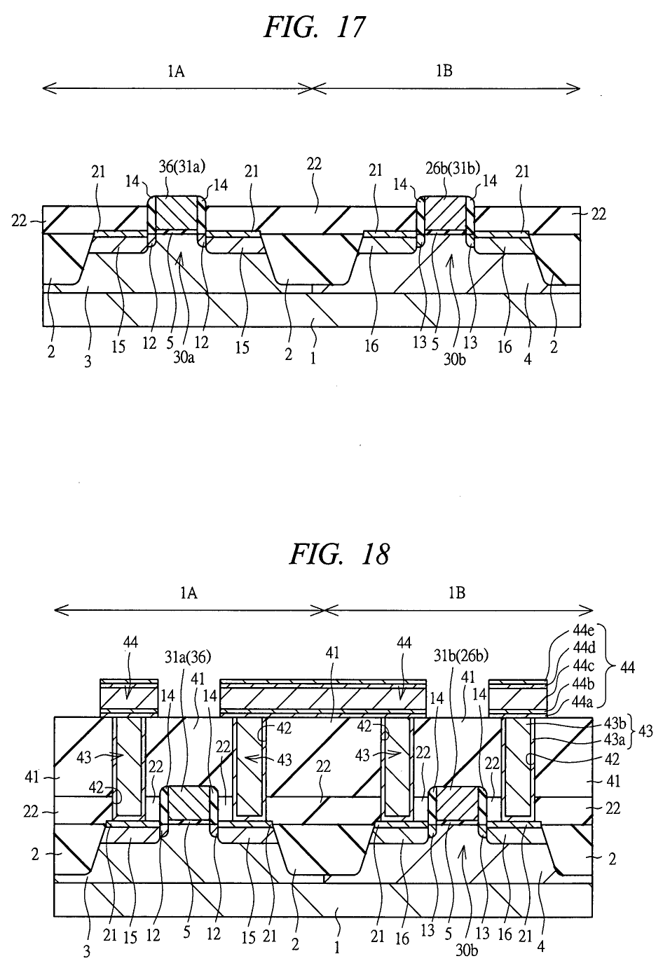

After the metal film 35a is formed, as shown in FIG. 17, the heat treatment similar to that of the above-described first embodiment is preformed to react the metal silicide film 26a with the metal film 35a in the n-channel type MISFET formation region 1A, thereby forming a conductive film 36 (i.e., the gate electrode 31a). For example, by performing the heat treatment at 400° C. in nitrogen gas atmosphere, the metal silicide film 26a and the metal film 35a in the n-channel type MISFET formation region 1A are reacted with each other to form the conductive film 36 similar to that of the above-described first embodiment. The metal film 35a is made of the same material as the above-mentioned metal film 35 of the first embodiment. Therefore, also in the present embodiment, by the reaction between the metal silicide film 26a and the metal film 35a through the heat treatment, the conductive film 36 similar to the above-described first embodiment (i.e., the gate electrode 31a) is formed. In this heat treatment, since the metal film 35a is not formed on the metal silicide film 26b (gate electrode 31b) of the p-channel type MISFET 30b, the metal silicide film 26b (gate electrode 31b) in the p-channel type MISFET formation region 1B is not reacted with the metal film 35a.

Thereafter, unreacted part of the metal film 35a is removed. For example, when the metal film 35a is made of Al, through the process using HNO₃/CH₃COOH/H₃PO₄ mixed solution, the unreacted metal film 35a can be removed. In this manner, the structure in FIG. 17 can be obtained.

Subsequent manufacturing processes are almost the same as the above-described first embodiment. More specifically, as shown in FIG. 18, the insulating film 41 is formed on the semiconductor substrate 1 and the upper surface of the insulating film 41 is planarized by using a technique such as CMP. After that, in the same manner as the above-described first embodiment, the contact holes 42, plugs 43, interconnects 44 are formed.

Also in the present embodiment, effects almost the same as those of the above-described first embodiment can be achieved. Further, in the present embodiment, after the metal silicide films 26a and 26b are formed as shown in FIG. 8, through the depositing process of the metal film 35a, the photolithography process, the dry-etching process of the metal film 35a, and the heat treatment process, the metal silicide film 26a in the n-channel type MISFET formation region 1A is reacted with the metal film 35a, thereby forming the gate electrode 31a (conductive film 36) of the n-channel type MISFET 30a. Accordingly, the number of manufacturing processes of semiconductor devices can be further reduced.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention is effectively applied to a semiconductor device comprising a MISFET having a metal gate electrode and a manufacturing technique thereof.

What is claimed is:

1. A manufacturing method of a semiconductor device including a first MISFET of p-channel type and a second MISFET of n-channel type, comprising the steps of:
(a) preparing a semiconductor substrate;
(b) forming a first gate electrode of the first MISFET and a dummy gate electrode of the second MISFET, which are formed of a metal silicide containing a first metal as its constituent element, on the semiconductor substrate;
(c) forming a metal film formed of a second metal having a work function lower than that of the first metal so that the metal film contacts with the dummy gate electrode but not with the first gate electrode; and
(d) performing a heat treatment to react the dummy gate electrode with the metal film, thereby forming a second gate electrode formed of a conductive film containing Si, the first metal, and the second metal as its constituent elements.

2. The manufacturing method of a semiconductor device according to claim 1,
wherein, in the step (d), the first gate electrode is not reacted with the metal film.

3. The manufacturing method of a semiconductor device according to claim 1,
wherein the heat treatment of the step (d) is a heat treatment performed at 600° C. or lower.

4. The manufacturing method of a semiconductor device according to claim 1,
wherein the step (b) comprises the steps of:
(b1) forming a gate insulator on the semiconductor substrate;
(b2) forming a first dummy electrode of the first MISFET made of silicon and a second dummy electrode of the second MISFET made of silicon on the gate insulator;
(b3) forming a first metal film formed of the first metal on the first dummy electrode and the second dummy electrode; and
(b4) performing a heat treatment to react the first dummy electrode with the first metal film, thereby forming the first gate electrode, and react the second dummy electrode with the first metal film, thereby forming the dummy gate electrode.

5. The manufacturing method of a semiconductor device according to claim 4,
wherein the heat treatment of the step (d) and the heat treatment of the step (b4) are a heat treatment performed at 300° C. or higher, respectively.

6. The manufacturing method of a semiconductor device according to claim 1,
wherein the first metal is at least one of those selected from a group of: Ni, Pt, Ru, Ir, Pd, and Co.

7. The manufacturing method of a semiconductor device according to claim 1,
wherein the first metal is Ni.

8. The manufacturing method of a semiconductor device according to claim 1,
wherein the second metal is at least one of those selected from a group of: Al, Hf, Ti, Zr, and Ta.

9. The manufacturing method of a semiconductor device according to claim 1,
wherein the second metal is Al.

10. The manufacturing method of a semiconductor device according to claim 1,
wherein the step (c) comprises the steps of:
(c1) forming a first material film to cover the first gate electrode and expose the dummy gate electrode; and
(c2) after the step (c1), forming the metal film on the first gate electrode and the dummy gate electrode, and
the metal film formed in the step (c2) contacts with the dummy gate electrode but not with the first gate electrode due to the first material film interposed therebetween.

11. The manufacturing method of a semiconductor device according to claim 10,
wherein, in the step (c1), after the first material film is formed on the semiconductor substrate so as to cover the first gate electrode and the dummy gate electrode,
the first material film is patterned, thereby forming the first material film which covers the first gate electrode and exposes the dummy gate electrode.

12. The manufacturing method of a semiconductor device according to claim 11,
wherein, in the heat treatment of the step (d), the first material film is not reacted with the first gate electrode and the metal film.

13. The manufacturing method of a semiconductor device according to claim 1,
wherein, in the step (c), after the metal film is formed on the semiconductor substrate so as to cover the first gate electrode and the dummy gate electrode, the metal film is patterned to remove the metal film on the first gate electrode and leave the metal film on the dummy gate electrode, thereby forming the metal film which contacts with the dummy gate electrode but not with the first gate electrode.

14. A manufacturing method of a semiconductor device having a first MISFET of p-channel type and a second MISFET of n-channel type, comprising the steps of:
(a) preparing a semiconductor substrate;
(b) forming a gate insulator on the semiconductor substrate;
(c) forming a first dummy electrode formed of silicon for the first MISFET and a second dummy electrode formed of silicon for the second MISFET on the gate insulator;
(d) forming a first metal film formed of a first metal on the first dummy electrode and the second dummy electrode;
(e) performing a heat treatment to react the first dummy gate electrode with the first metal film, thereby forming a first gate electrode of the first MISFET made of metal silicide containing the first metal as its constituent element, and react the second dummy electrode with the first metal film, thereby forming a dummy gate electrode of the second MISFET made of metal silicide containing the first metal as its constituent element;
(f) forming a second metal film formed of a second metal having a work function lower than that of the first metal so as to contact with the dummy gate electrode but not with the first gate electrode; and
(g) performing a thermal treatment to react the dummy gate electrode with the second metal film, thereby forming a second gate electrode of the second MISFET.

15. The manufacturing method of a semiconductor device according to claim 14,
wherein the second metal is Al.

16. The manufacturing method of a semiconductor device according to claim 14,
wherein the step (f) comprises the steps of:
(f1) forming a first material film so as to cover the first gate electrode and expose the dummy gate electrode; and
(f2) after the step (f2), forming the second metal film on the first gate electrode and the dummy gate electrode, and
the second metal film formed in the step (f2) contacts with the dummy gate electrode but not with the first gate electrode due to the first material film interposed therebetween.

17. The manufacturing method of a semiconductor device according to claim 14,
wherein, in the step (f), after the second metal film is formed on the semiconductor substrate so as to cover the first gate electrode and the dummy gate electrode, the second metal film is patterned to remove the second metal film on the first gate electrode and leave the second metal film on the dummy gate electrode, thereby forming the second metal film which contacts with the dummy gate electrode but not with the first gate electrode.

18. A semiconductor device comprising:
a first MISFET of p-channel type; and
a second MISFET of n-channel type,
wherein a first gate electrode of the first MISFET is formed of a metal silicide film containing Si and a first metal as its constituent elements, and
a second gate electrode of the second MISFET is formed of a conductive film containing Si, the first metal, and a second metal having a work function lower than that of the first metal.

19. The semiconductor device according to claim 18,
wherein the first metal is Ni, and
the second metal is Al.

20. The semiconductor device according to claim 19,
wherein the first gate electrode is made of nickel silicide, and
the second gate electrode is formed of the conductive film made of nickel silicide to which Al is introduced.
